(19) United States
(12) Patent Application Publication
(10) Pub. No.: US 2026/0271717 A1
(43) Pub. Date: Sep. 10, 2026

(54) SEMICONDUCTOR PACKAGE AND METHOD OF FABRICATING THE SAME

(71) Applicant: Taiwan Semiconductor Manufacturing Company, Ltd., Hsinchu (TW)

(72) Inventors: Ming-Tsu Chung, Hsinchu City (TW); Chen Sheng Wu, Hsinchu (TW); Yu-Han Wang, Hsinchu (TW); Yung-Chi Lin, New Taipei City (TW)

(73) Assignee: Taiwan Semiconductor Manufacturing Company, Ltd., Hsinchu (TW)

(21) Appl. No.: 19/070,435

(22) Filed: Mar. 4, 2025

(51) Int. Cl. H01L 23/373; H01L 21/48; H01L 23/00; H01L 23/14; H01L 23/31; H01L 23/538

(52) U.S. Cl. CPC H10W 40/257; H10W 70/60; H10W 70/611; H10W 70/698; H10W 99/00; H10W 72/073; H10W 72/322; H10W 74/114; H10W 90/734; H10W 90/794

(57) ABSTRACT

A semiconductor package includes a substrate, a coating material, a first bonding film, semiconductor chips, an interconnection structure and a plurality of conductive bumps. The substrate has a first surface and a second surface opposite to the first surface, wherein pores are located on the first surface and on the second surface of the substrate. The coating material is provided in the pores exposed on the second surface of the substrate, wherein the pores exposed on the second surface are entirely filled with the coating material. The first bonding film is located on the substrate and contacting the coating material and the second surface of the substrate. The semiconductor chips are located on the first bonding film. The interconnection structure is electrically connected to the semiconductor chips. The conductive bumps are disposed on and electrically connected to the interconnection structure.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 11 are schematic sectional views of various stages in a method of fabricating a semiconductor package according to some exemplary embodiments of the present disclosure.

FIG. 12 is a schematic sectional view of a semiconductor package according to some other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Introducing high thermal conductivity materials (>1.3 times higher than Si) into System-on-Integrated-Chips (SoIC) may be commonly applied for providing thermal solutions. Current studies have shown the potential of using sintered silicon carbide (SiC) carriers for providing thermal solution. However, sintered SiC carriers are shown to have a porous structure with irregular structure/shapes. As a result, irregular surfaces are generally observed on sintered SiC carriers. The formation of films on the irregular surfaces of the sintered SiC carriers through deposition techniques (such as chemical vapor deposition (CVD)) may result in seams, which causes a problem of thermal resistance.

In accordance with some embodiments of the present disclosure, a method of fabricating a semiconductor package is described, whereby a coating material is formed to fill up the pores exposed on the surfaces of the carrier substrate. Thus, the irregular surfaces of the carrier are planarized, whereby the formation of seams is minimized and a reduction in the thermal resistance can be achieved.

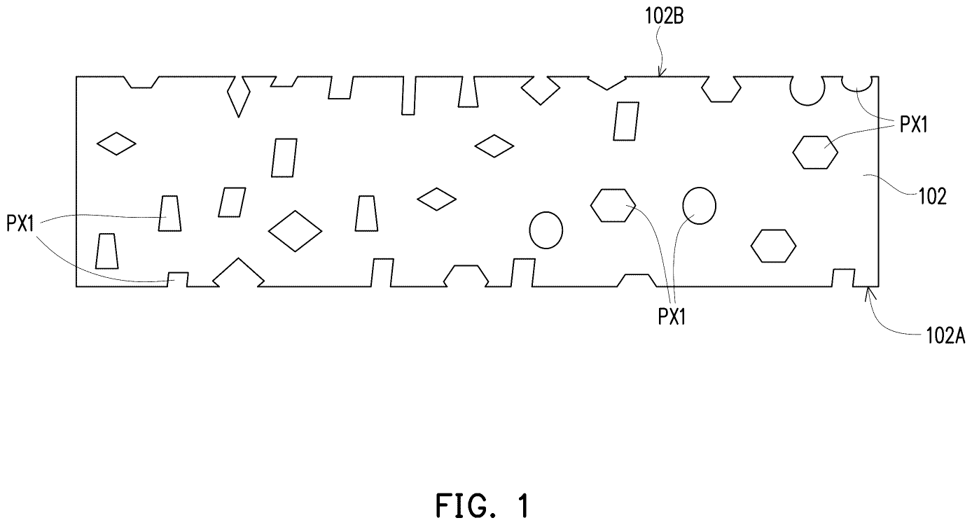

FIG. 1 to FIG. 11 are schematic sectional views of various stages in a method of fabricating a semiconductor package according to some exemplary embodiments of the present disclosure. Referring to FIG. 1, a carrier substrate 102 is provided. In some embodiments, the carrier substrate 102 is a porous substrate, or a sintered silicon carbide (SiC) porous substrate having a plurality of pores PX1 (or air voids) located therein. In certain embodiments, the sintered SiC porous substrate has a porosity of 1% to 25%, which may be adjusted based on design requirements. As further illustrated in FIG. 1, the carrier substrate 102 has a first surface 102A and a second surface 102B opposite to the first surface 102A. In some embodiments, the pores PX1 are exposed and located on the first surface 102A and on the second surface 102B of the carrier substrate 102. In other words, the first surface 102A and the second surface 102B are irregular surfaces. Furthermore, some pores PX1 are also located within the body of the carrier substrate 102, and are not exposed at the first surface 102A and the second surface 102B.

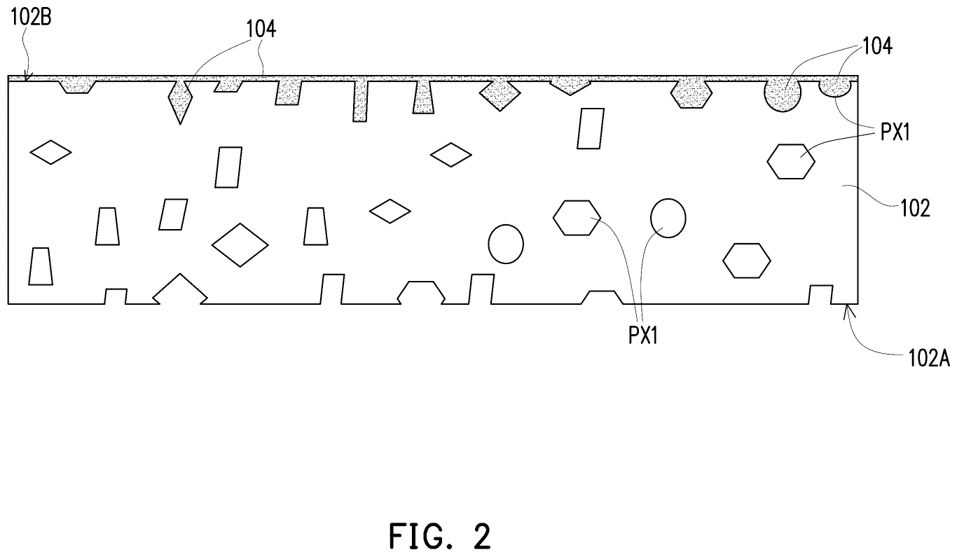

Referring to FIG. 2, in some embodiments, a coating process is performed so that a coating material 104 is formed on the second surface 102B of the carrier substrate 102 to fill up the pores PX1 exposed on the second surface 102B. In certain embodiments, the coating material 104 entirely fill up the pores PX1 exposed on the second surface 102B. For example, the coating material 104 are spin coating materials such as flowable oxide materials or spin-on-glass (SOG) materials.

In some embodiments, the flowable oxide materials are formed by using hydrogen silsesquioxane in a carrier solvent for performing a flowable oxide spin coating process to form flowable oxide materials in the pores PX1 exposed on the second surface 102B of the carrier substrate 102. Furthermore, the flowable oxide spin coating process is performed under an ozone (O₃) atmosphere, and cured at a temperature of 100° C. to 1500° C. with a curing time of 0.5 to 10 hours to form the coating material 104. In certain embodiments, the flowable oxide spin coating process is performed under an ozone (O₃) atmosphere, and cured at a temperature of 150° C. to 800° C. with a curing time of 0.5 to 4 hours to form the coating material 104.

In some embodiments, the spin-on-glass (SOG) materials are formed by using a silica or silicate-based liquid compound (either doped or undoped) for performing a spin-on-glass (SOG) spin coating process to form SOG materials in the pores PX1 exposed on the second surface 102B of the carrier substrate 102. Furthermore, the SOG spin coating process is performed under a nitrogen gas (N₂) atmosphere, and cured at a temperature of 150° C. to 300° C. with a curing time of 0.5 to 4 hours to form the coating material 104.

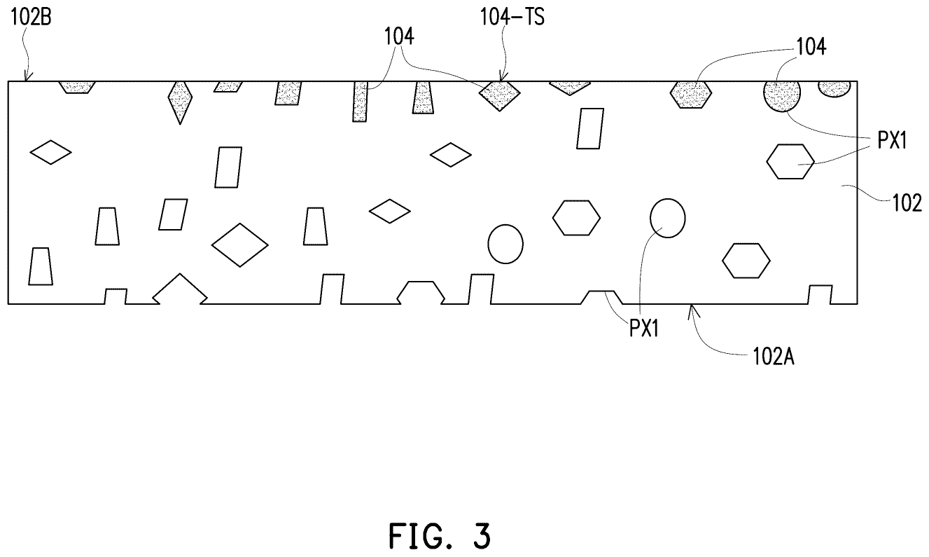

As illustrated in FIG. 2, the coating material 102 are formed to fill up the pores PX2 exposed on the second surface 102B of the carrier substrate 102, and are further formed to cover the second surface 102B of the carrier substrate 102. Subsequently, referring to FIG. 3, a planarization step such as a chemical-mechanical polishing (CMP) step is performed to remove portions of the coating material 102 located above the second surface 102B. After the planarization step, a top surface 104-TS of the coating material 104 is aligned with the second surface 102B of the carrier substrate 102.

In the exemplary embodiment, the coating material 104 is formed on the second surface 102B, wherein the first surface 102A is free of the coating material 104. The pores PX1 located within the carrier substrate 102 (e.g. in the body of the carrier substrate 102) are also not exposed at the first surface 102A or the second surface 102B, thus are also free of the coating material 104. In some embodiments, after forming the coating material 104, an amount of pores PX1 or air voids located at the first surface 102A is greater than an amount of pores PX1 or air voids located at the second surface 102B of the carrier substrate 102. In some embodiments, approximately 90% to 100% of a volume of the pores PX1 located at the second surface 102B is occupied by the coating material 104 after the coating process. In certain embodiments, 95% to 100% of the volume of the pores PX1 located at the second surface 102B is occupied by the coating material 104 after the coating process. In certain embodiments, 98% to 100% of the volume of the pores PX1 located at the second surface 102B is occupied by the coating material 104 after the coating process. In certain embodiments, the pores PX1 located at the second surface 102B are entirely occupied by the coating material 104 after the coating process. In some embodiments, due to the presence of the coating material 104 on the second surface 102B, the second surface 102B of the carrier substrate 102 is free of pores PX1 or free of the air voids/seams. As such, the second surface 102B of the carrier substrate 102 is a substantially planar surface, while the first surface 102A of the carrier substrate 102 is an irregular surface (having air voids).

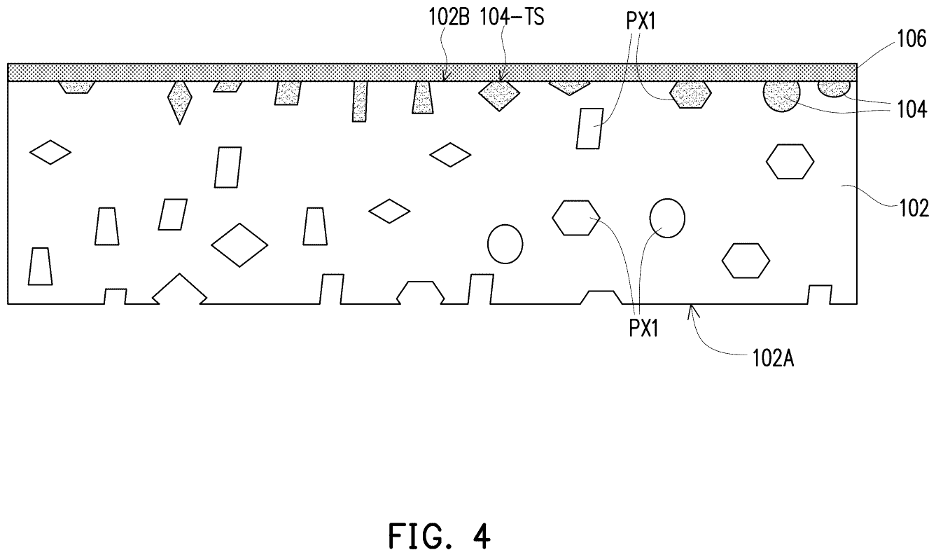

Referring to FIG. 4, in a subsequent step, a first bonding film 106 is formed on the carrier substrate 102. For example, the first bonding film 106 is directly contacting the top surface 104-TS of the coating material 104 and contacting the second surface 102B of the carrier substrate 102. In some embodiments, the first bonding film 106 is formed by thin film deposition techniques, such as atomic layer deposition (ALD), sputtering or the like. Furthermore, the first bonding film 106 may include materials selected from the group consisting of aluminum monoxide (AlO), aluminum nitride (AlN), silicon carbide (SiC), silicon carbonitride (SiCN), silicon nitride (SiN), silicon monoxide (SiO), titanium nitride (TiN), or the like.

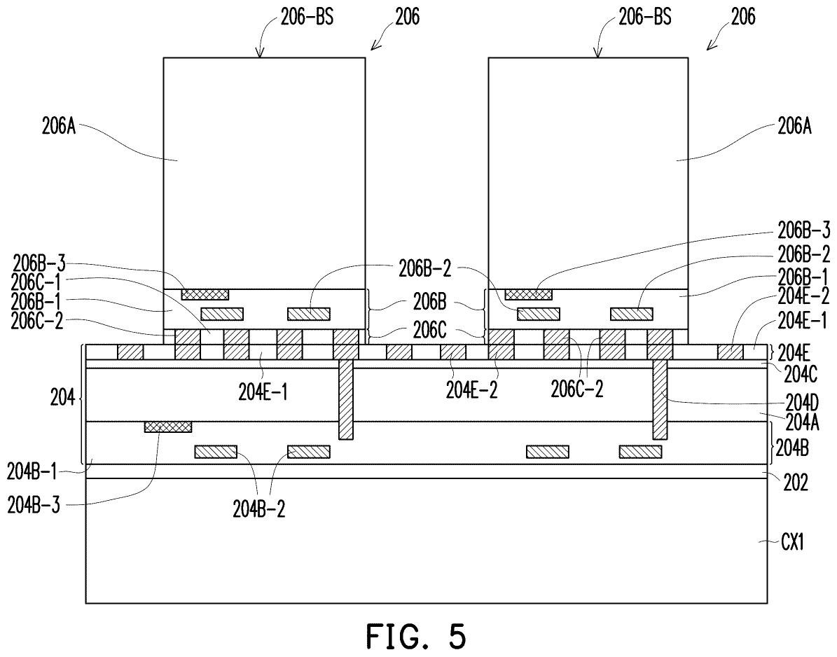

After forming the first bonding film 106 on the carrier substrate 102, the details of bonding semiconductor chips 206 and an interconnection structure 204 on the first bonding film 106 will be described. Referring to FIG. 5, a first carrier CX1 is provided. In some embodiments, the first carrier CX1 may be a glass carrier or any suitable carrier for carrying a semiconductor wafer or a reconstituted wafer for the manufacturing method of the semiconductor package. In some embodiments, the first carrier CX1 is coated with a debond layer 202. The material of the debond layer 202 may be any material suitable for bonding and de-bonding the first carrier CX1 from the above layer(s) or any wafer(s) disposed thereon.

In some embodiments, the debond layer 202 may include a dielectric material layer made of a dielectric material including any suitable polymer-based dielectric material (such as benzocyclobutene (“BCB”), polybenzoxazole (“PBO”)). In an alternative embodiment, the debond layer 202 may include a dielectric material layer made of an epoxy-based thermal-release material, which loses its adhesive property when heated, such as a light-to-heat-conversion (LTHC) release coating film. In a further alternative embodiment, the debond layer 202 may include a dielectric material layer made of an ultra-violet (UV) glue, which loses its adhesive property when exposed to UV lights. In certain embodiments, the debond layer 202 may be dispensed as a liquid and cured, or may be a laminate film laminated onto the first carrier CX1, or may be the like. The top surface of the debond layer 202, which is opposite to a bottom surface contacting the first carrier CX1, may be leveled and may have a high degree of coplanarity. In certain embodiments, the debond layer 202 is, for example, a LTHC layer with good chemical resistance, and such layer enables room temperature de-bonding from the first carrier CX1 by applying laser irradiation, however the disclosure is not limited thereto.

In an alternative embodiment, a buffer layer (not shown) may be coated on the debond layer 202, where the debond layer 202 is sandwiched between the buffer layer and the first carrier CX1, and the top surface of the buffer layer may further provide a high degree of coplanarity. In some embodiments, the buffer layer may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

Referring to FIG. 5, in a subsequent step, an interconnection structure 204 is formed on the debond layer 202. In some embodiments, the interconnection structure 204 is a semiconductor wafer, or an interposer structure. In the exemplary embodiment, the interconnection structure 204 is formed with a semiconductor substrate 204A, a redistribution layer 204B, a passivation layer 204C, through substrate vias 204D, and a bonding layer 204E. The semiconductor substrate 204A may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. For example, a device 204B-3 (active or passive devices) may be located on the semiconductor substrate 204A, and embedded in the redistribution layer 204B.

As further illustrated in FIG. 5, the interconnection structure 204 is disposed on the debond layer 202 so that the redistribution layer 204B is sandwiched in between the semiconductor substrate 204A and the debond layer 202. In some embodiments, the formation of the redistribution layer 204B includes forming a plurality of dielectric layers 204B-1 and a plurality of conductive elements 204B-2 that are alternately stacked. The number of dielectric layers 204B-1 and the number of conductive elements 204B-2 is not particularly limited in the disclosure, and may be adjusted based on product requirements.

In some embodiments, a material of the dielectric layers 204B-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 204B-1 may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 204B-2 may be made of conductive materials formed by electroplating or deposition, such as aluminum, titanium, copper, nickel, tungsten, and/or alloys thereof, which may be patterned using a photolithography and etching process. In some embodiments, the conductive elements 204B-2 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

As further illustrated in FIG. 5, the passivation layer 204C is formed on a surface of the semiconductor substrate 204A, opposite to a surface where the redistribution layer 204B is located. In some embodiments, the passivation layer 204C is formed by depositing a dielectric material, such as silicon oxide, silicon nitride, or the like, and performing a planarization process to remove the excess portions of the dielectric material to reveal the through substrate vias 204D. Furthermore, in some embodiments, the through substrate vias 204D extends from the redistribution layer 204B through the semiconductor substrate 204A towards a surface of the passivation layer 204C. For example, the through substrate vias 204D are electrically connecting the redistribution layer 204B to the bonding layer 204E.

In some embodiments, the bonding layer 204E is formed on the passivation layer 204C. For example, forming the bonding layer 204E includes forming a dielectric layer 204E-1 and a plurality of bonding pads 204E-2 embedded in the dielectric layer 204E-1. In some embodiments, the bonding pads 204E-2 are made of conductive materials formed by electroplating or deposition, and include materials such as copper, copper alloys, or other suitable metallic materials which may be patterned using a photolithography and etching process. Furthermore, the dielectric layer 204E-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 204E-1 is formed by suitable fabrication techniques such as spin-on coating, chemical vapor deposition (CVD), plasma-enhanced chemical vapor deposition (PECVD) or the like. The disclosure is not limited thereto.

After forming the interconnection structure 204 on the debond layer 202 and on the first carrier CX1, a plurality of semiconductor chips 206 is bonded onto the interconnection structure 204. In the exemplary embodiment, each of the semiconductor chips 206 includes a semiconductor substrate 206A, a redistribution layer 206B and a bonding layer 206C. The semiconductor substrate 206A may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. For example, a device 206B-3 (active or passive devices) may be located on the semiconductor substrate 206A, and embedded in the redistribution layer 206B.

In some embodiments, the redistribution layer 206B is located on the semiconductor substrate 206A. Furthermore, after bonding the semiconductor chips 206 onto the interconnection structure 204, the redistribution layer 206B is located in between the semiconductor substrate 206A of the semiconductor chips 206 and the bonding layer 204C of the interconnection structure 204. In some embodiments, the formation of the redistribution layer 206B includes forming a plurality of dielectric layers 206B-1 and a plurality of conductive elements 206B-2 that are alternately stacked. The number of dielectric layers 206B-1 and the number of conductive elements 206B-2 is not particularly limited in the disclosure, and may be adjusted based on product requirements.

In some embodiments, a material of the dielectric layers 206B-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 206B-1 may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 206B-2 may be made of conductive materials formed by electroplating or deposition, such as aluminum, titanium, copper, nickel, tungsten, and/or alloys thereof, which may be patterned using a photolithography and etching process. In some embodiments, the conductive elements 206B-2 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the bonding layer 206C is formed on the redistribution layer 206B. For example, forming the bonding layer 206C includes forming a dielectric layer 206C-1 and a plurality of bonding pads 206C-2 embedded in the dielectric layer 206C-1. In some embodiments, the bonding pads 206C-2 are made of conductive materials formed by electroplating or deposition, and include materials such as copper, copper alloys, or other suitable metallic materials which may be patterned using a photolithography and etching process. Furthermore, the dielectric layer 206C-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 206C-1 is formed by suitable fabrication techniques such as spin-on coating, chemical vapor deposition (CVD), plasma-enhanced chemical vapor deposition (PECVD) or the like. The disclosure is not limited thereto.

In the exemplary embodiment, the semiconductor chips 206 are bonded onto the interconnection structure 204 by bonding the bonding layer 204E to the bonding layer 206C. For example, the dielectric layer 204E-1 is joined with the dielectric layer 206C-1 through dielectric-to-dielectric bonding, and the bonding pads 204E-2 are joined with the bonding pads 206C-2 through direct metal-to-metal bonding. In some embodiments, the bonding layer 204E is joined to the bonding layer 206C so that a portion of the bonding pads 204E-2 of the interconnection structure 204 are revealed (uncovered) by the semiconductor chips 206. In other words, some of the bonding pads 204E-2 are dummy pads that do not have electrical connection with (or are electrically isolated from) the semiconductor chips 206. Although two semiconductor chips 206 are illustrated as being bonded to the interconnection structure 204, it is noted that the number of semiconductor chips 206 bonded to the interconnection structure 204 is not limited thereto, and may be adjusted based on product requirements.

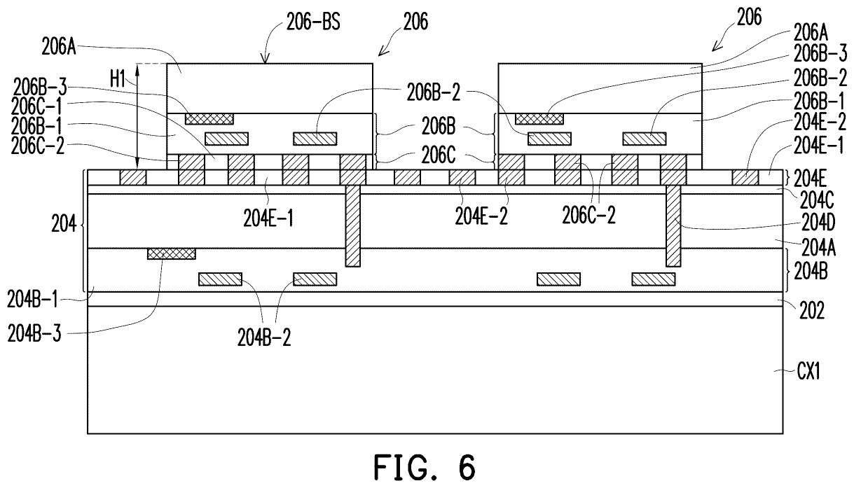

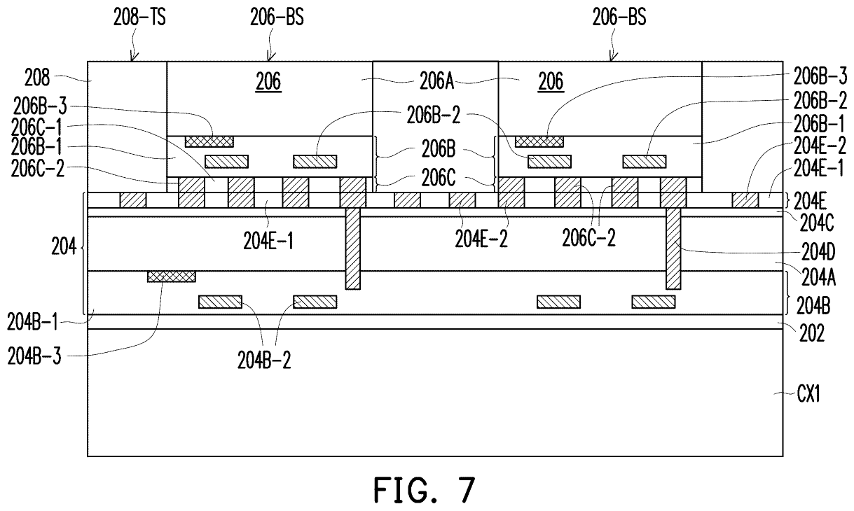

Referring to FIG. 6, in a subsequent step, backsides 206-BS of the semiconductor chips 206 are thinned down so that the semiconductor chips 206 have a first height H1. In some embodiments, the semiconductor chips 206 are thinned down by removing portions of the semiconductor substrate 206A. Subsequently, referring to FIG. 7, a gap fill layer 208 is formed on the interconnection structure 204 and covering the semiconductor chips 206. In some embodiments, the gap fill layer 208 may be formed of a dielectric material, such as an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. Furthermore, a planarization step is performed through a mechanical grinding process and/or a chemical mechanical polishing (CMP) process to remove portions of the gap fill layer 208, so that a top surface 208-TS of the gap fill layer 208 is aligned and leveled with backsides 206-BS of the semiconductor chips 206. In some embodiments, after the mechanical grinding or chemical-mechanical polishing (CMP) steps, a cleaning step may be optionally performed. For example, the cleaning step is preformed to clean and remove the residue generated from the planarization step. However, the disclosure is not limited thereto, and the planarization step may be performed through any other suitable methods.

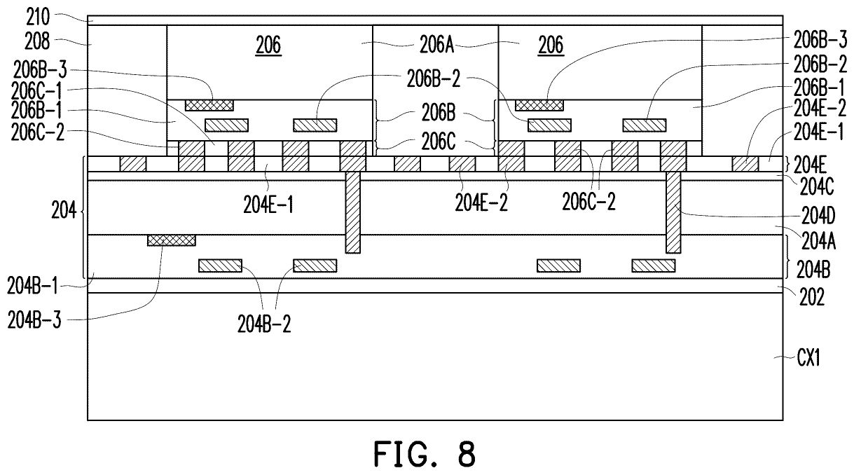

Referring to FIG. 8, after forming the gap fill layer 208, a second bonding film 210 is formed on the backsides 206-BS of the semiconductor chips 206, and formed on the top surface 208-TS of the gap fill layer 208. In some embodiments, the second bonding film 210 is formed by thin film deposition techniques, such as atomic layer deposition (ALD), sputtering or the like. Furthermore, the second bonding film 210 may include materials selected from the group consisting of aluminum monoxide (AlO), aluminum nitride (AlN), silicon carbide (SiC), silicon carbonitride (SiCN), silicon nitride (SiN), silicon monoxide (SiO), titanium nitride (TiN), or the like.

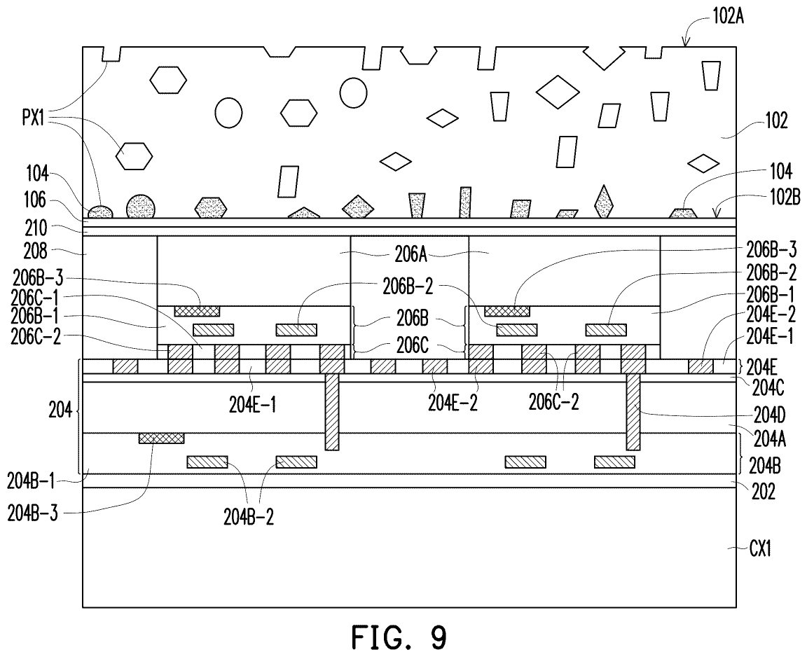

Referring to FIG. 9, in a subsequent step, the carrier substrate 102 is bonded onto the backsides 206-BS of the semiconductor chips 206 and on the top surface 208-TS of the gap fill layer 208. In some embodiments, the carrier substrate 102 is bonded to the second bonding film 210 located on the semiconductor chips 206 and on the gap fill layer 208 through the first bonding film 106. In other words, the first bonding film 106 is directly joined with the second bonding film 210. After bonding the carrier substrate 102 onto the backsides 206-BS of the semiconductor chips 206, the first bonding film 106 is located in between the carrier substrate 102 and the second bonding film 210, while the second bonding film 210 is located in between the first bonding film 106 and the semiconductor chips 206. In the exemplary embodiment, the carrier substrate 102 is bonded onto the backsides 206-BS of the semiconductor chips 206 so that the second surface 102B having the coating material 104 is facing the semiconductor chips 206 and facing the gap fill layer 208, while the first surface 102A having the irregular surface is facing away from the semiconductor chips 206 and the gap fill layer 208.

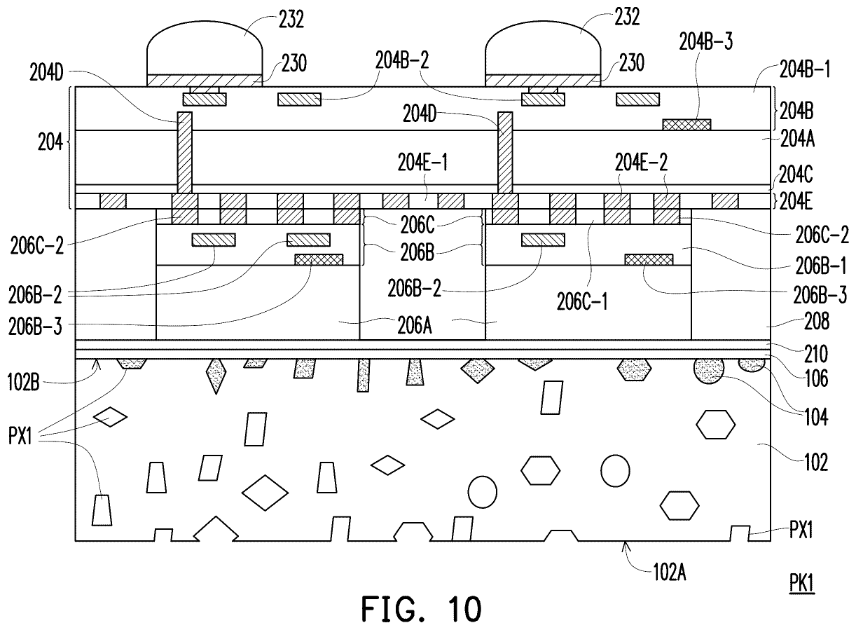

Referring to FIG. 10, after bonding the carrier substrate 102 onto the backsides 206-BS of the semiconductor chips 206, the structure shown in FIG. 9 is flipped around, and the first carrier CX1 is debonded/removed to separate the interconnection structure 204 from the first carrier CX1. In some embodiments, the debonding process include projecting a light such as a laser light or an UV light on the debond layer 202, so that the first carrier CX1 can be easily removed. As illustrated in FIG. 10, upon removing the first carrier CX1, a surface of the redistribution layer 204B is exposed. In some embodiments, the dielectric layers 204B-1 of the redistribution layer 204B are patterned to form openings revealing the conductive elements 204B-2. Thereafter, a plurality of conductive pads 230 are formed in the openings to be electrically connected to the conductive elements 204B-2. In some embodiments, the conductive pads 230 are for example, under-ball metallurgy (UBM) patterns used for ball mount. In some embodiments, the materials of the conductive pads 230 may include copper, nickel, titanium, tungsten, or alloys thereof or the like, and may be formed by an electroplating process, for example. The number of conductive pads 230 are not limited in this disclosure, and may be selected based on the design layout.

After forming the conductive pads 230, a plurality of conductive bumps 232 is disposed on the conductive pads 230 and over the interconnection structure 204. In some embodiments, the conductive bumps 232 may be disposed on the conductive pads 230 by a ball placement process or reflow process. In some embodiments, the conductive bumps 232 are solder bumps, lead-free solder bumps, or micro bumps, such as controlled collapse chip connection (C4) bumps or micro bumps containing copper pillars, or the like. In some embodiments, the conductive bumps 232 are electrically connected to the redistribution layer 204B of the interconnection structure 204 through the conductive pads 230. After forming the conductive pads 230 and conductive bumps 232, multiple first packages PK1 including the above package components are formed on the same carrier substrate(s) and then singulated to form an individual first package PK1.

In the singulated first package PK1, sidewalls of the carrier substrate 102 are aligned with sidewalls of the gap fill layer 208, and aligned with sidewalls of the interconnection structure 204. Furthermore, sidewalls of the first bonding film 106 and the second bonding film 210 are also aligned with sidewalls of the gap fill layer 208, and aligned with sidewalls of the interconnection structure 204.

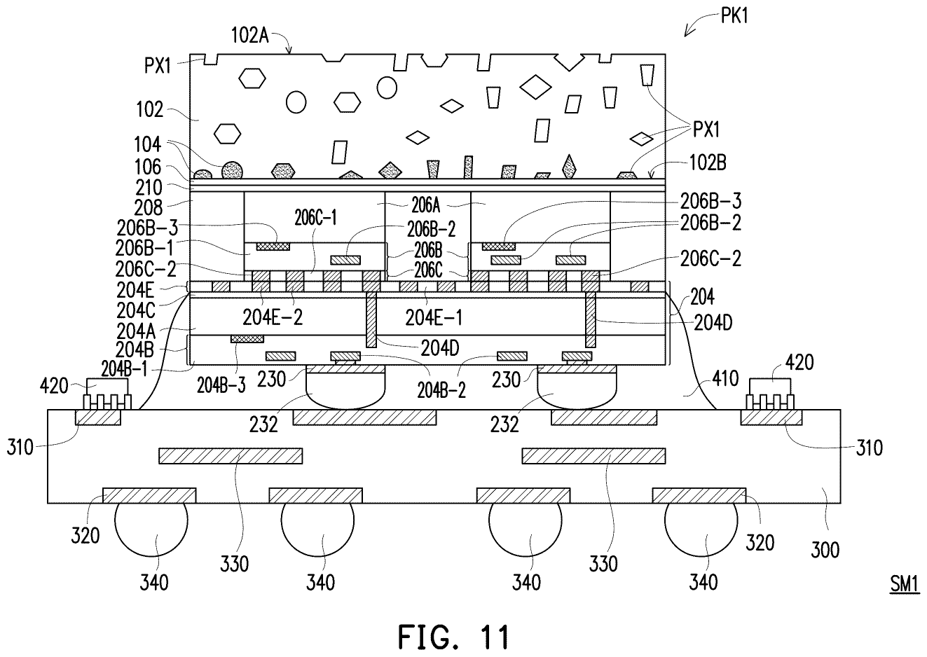

Referring to FIG. 11, after forming the first package PK1 shown in in FIG. 10, the first package PK1 is mounted or attached onto a circuit substrate 300 through the conductive bumps 232. In some embodiments, the circuit substrate 300 includes contact pads 310, contact pads 320, metallization layers 330, and vias (not shown). In some embodiments, the contact pads 310 and the contact pads 320 are respectively distributed on two opposite sides of the circuit substrate 300, and are exposed for electrically connecting with later-formed elements/features. In some embodiments, the metallization layers 330 and the vias are embedded in the circuit substrate 300 and together provide routing function for the circuit substrate 300, wherein the metallization layers 330 and the vias are electrically connected to the contact pads 310 and the contact pads 320. In other words, at least some of the contact pads 310 are electrically connected to some of the contact pads 320 through the metallization layers 330 and the vias. In some embodiments, the contact pads 310 and the contact pads 320 may include metal pads or metal alloy pads. In some embodiments, the materials of the metallization layers 330 and the vias may be substantially the same or similar to the material of the contact pads 310 and the contact pads 320.

Furthermore, in some embodiments, the first package PK1 is bonded to the circuit substrate 300 through physically connecting the conductive bumps 232 and the contact pads 310 to form a stacked structure. In certain embodiments, the first package PK1 is electrically connected to the circuit substrate 300. In some embodiments, the circuit substrate 300 is such as an organic flexible substrate or a printed circuit board. In some embodiments, a plurality of conductive balls 340 are respectively formed on the circuit substrate 300. As illustrated in FIG. 11, for example, the conductive balls 340 are connected to the contact pads 320 of the circuit substrate 300. In other words, the conductive balls 340 are electrically connected to the circuit substrate 300 through the contact pads 320. Through the contact pads 310 and the contact pads 320, some of the conductive balls 340 are electrically connected to the first package PK1. In some embodiments, the conductive balls 340 are, for example, solder balls or ball grid array (BGA) balls.

As further illustrated in FIG. 11, in some embodiments, passive devices 420 (integrated passive device or surface mount devices) may be mounted on the circuit substrate 300. For example, the passive devices 420 may be mounted on the contact pads 310 of the circuit substrate 300 through a soldering process. The disclosure is not limited thereto. In certain embodiments, the passive devices 420 may be mounted on the circuit substrate surrounding the first package PK1. In some embodiments, an underfill structure 410 is formed to fill up the spaces in between the circuit substrate 300 and the first package PK1. In certain embodiments, the underfill structure 410 fills up the spaces in between adjacent conductive bumps 232 and covers the conductive bumps 232. For example, the underfill structure 410 surrounds the plurality of conductive bumps 232. In some embodiments, the passive devices 420 is exposed by the underfill structure 410, and kept a distance apart from the underfill structure 410. In other words, the underfill structure 410 does not cover the passive devices 420. Up to here, a semiconductor package SM1 in accordance with some embodiments of the present disclosure is accomplished.

In the semiconductor package SM1, since a coating material 104 is formed on the second surface 102B of the carrier substrate 102 through a flowable oxide spin coating process or a spin-on-glass (SOG) spin coating process, the irregular surfaces on the second surface 102B of the carrier substrate 102 are planarized, the formation of seams is minimized and a reduction in the thermal resistance of the semiconductor package SM1 can be achieved.

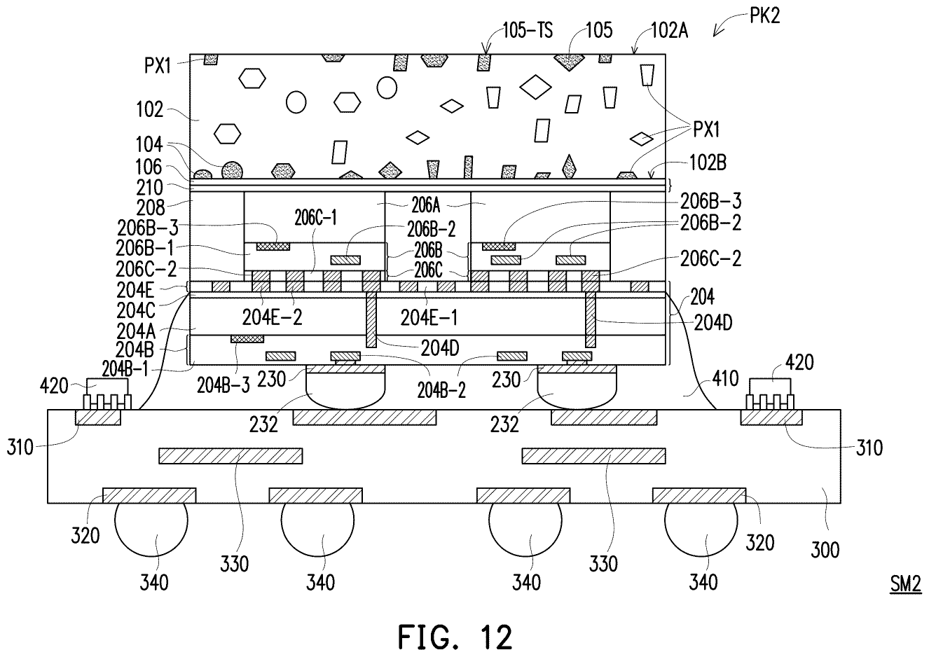

FIG. 12 is a schematic sectional view of a semiconductor package according to some other exemplary embodiments of the present disclosure. The semiconductor package SM2 illustrated in FIG. 12 is similar to the semiconductor package PK1 illustrated in FIG. 11. Therefore, the same reference numerals are used to refer to the same or liked parts, and its detailed description is omitted herein. The difference between the embodiments is that the first package PK1 of FIG. 11 is replaced with another package PK2.

As shown in the first package PK1 of FIG. 11, the coating material 104 is formed on the second surface 102B of the carrier substrate 102, while the first surface 102A of the carrier substrate 102 is free of the coating material 104. In other words, the first surface 102A of the carrier substrate 102 is an irregular surface that include exposed pores PX1 (or air voids). However, the disclosure is not limited thereto. In some embodiments, in the package PK2 shown in FIG. 12, the coating material 104 is formed on the second surface 102B of the carrier substrate 102, while another coating material 105 is formed on the first surface 102A of the carrier substrate 102. For example, the coating material 105 is filling up the pores PX1 that are exposed on the first surface 102A.

In some embodiments, the coating material 105 is formed by a flowable oxide spin coating process or a spin-on-glass (SOG) spin coating process in the same way as for forming the coating material 104. Thus, the details of forming the coating material 105 will not be repeated herein. In the exemplary embodiment, the coating material 105 is formed on the first surface 102A and are further planarized, so that the top surface 105-TS of the coating material 105 is aligned and leveled with the first surface 102A of the carrier substrate 102. In some embodiments, since the first surface 102A of the carrier substrate 102 is planarized due to the presence of the coating material 105, further elements such as thermal interface materials (not shown) or lid structures may be disposed on the first surface 102A of the carrier substrate 102.

In the semiconductor package SM2, since coating materials 104, 105 are formed on the first surface 102A and the second surface 102B of the carrier substrate 102 through a flowable oxide spin coating process or a spin-on-glass (SOG) spin coating process, the irregular surfaces on the first and second surfaces 102A, 102B of the carrier substrate 102 are planarized, thus the formation of seams is minimized and a reduction in the thermal resistance of the semiconductor package SM1 can be achieved.

In the above-mentioned embodiments, in a method of fabricating a semiconductor package, since a coating material is formed on the surface of the carrier substrate through a flowable oxide spin coating process or a spin-on-glass (SOG) spin coating process, the irregular surfaces of the carrier substrate are planarized. In other words, the coating material may fill up the exposed pores located on the surfaces of the carrier substrate reducing the formation of seams or air voids. Therefore, the problem of seams or air voids formed by using deposition techniques (such as chemical vapor deposition (CVD)) can be resolved. As a result, a reduction in the thermal resistance of the semiconductor package can be achieved.

In accordance with some embodiments of the present disclosure, a semiconductor package includes a carrier substrate, a coating material, a first bonding film, semiconductor chips, an interconnection structure and a plurality of conductive bumps. The carrier substrate has a first surface and a second surface opposite to the first surface, wherein pores are located on the first surface and on the second surface of the carrier substrate. The coating material is provided in the pores exposed on the second surface of the carrier substrate, wherein the pores exposed on the second surface are entirely filled with the coating material. The first bonding film is located on the carrier substrate and contacting the coating material and the second surface of the carrier substrate. The semiconductor chips are located on the first bonding film. The interconnection structure is electrically connected to the semiconductor chips. The conductive bumps are disposed on and electrically connected to the interconnection structure.

In accordance with some other embodiments of the present disclosure, a semiconductor package includes a first package and a circuit substrate. The first package includes a porous substrate, a plurality of semiconductor chips, an interconnection structure and a plurality of conductive bumps. The porous substrate has a first surface and a second surface opposite to the second surface, wherein an amount of air voids located at the first surface is greater than an amount of air voids located at the second surface. The semiconductor chips are located on the porous substrate. The interconnection structure is electrically connected to the semiconductor chips. The conductive bumps are electrically connected to the interconnection structure. The first package is bonded to circuit substrate so that the conductive bumps are joined with the contact pads of the circuit substrate.

In accordance with yet another embodiment of the present disclosure, a method of fabricating a semiconductor package is described. The method includes the following steps. A carrier substrate is provided, wherein the carrier substrate has a first surface and a second surface opposite to the first surface, and pores are located on the first surface and on the second surface of the carrier substrate. A coating material is formed to entirely fill up the pores exposed on the second surface of the carrier substrate. A first bonding film is formed on the carrier substrate, wherein the first bonding film is contacting the coating material and the second surface of the carrier substrate. Semiconductor chips and an interconnection structure are bonded on the first bonding film, wherein the semiconductor chips are located on the first bonding film, and the interconnection structure is electrically connected to the semiconductor chips. Conductive bumps are formed to be disposed on and electrically connected to the interconnection structure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate having a first surface and a second surface opposite to the first surface, wherein pores are located on the first surface and on the second surface of the substrate;
a coating material provided in the pores exposed on the second surface of the substrate, wherein the pores exposed on the second surface are entirely filled with the coating material;
a first bonding film located on the substrate and contacting the coating material and the second surface of the substrate;
semiconductor chips located on the first bonding film;
an interconnection structure electrically connected to the semiconductor chips; and
a plurality of conductive bumps disposed on and electrically connected to the interconnection structure.

2. The semiconductor package according to claim 1, wherein the coating material include flowable oxide materials or spin-on-glass (SOG) materials.

3. The semiconductor package according to claim 1, wherein a top surface of the coating material is aligned with the second surface of the substrate, and wherein the first surface of the substrate is free of the coating material.

4. The semiconductor package according to claim 1, wherein the substrate is a sintered silicon carbide (SiC) porous substrate.

5. The semiconductor package according to claim 1, further comprising:
a second bonding film located in between the first bonding film and the semiconductor chips; and
a gap fill layer located on the second bonding film and surrounding the semiconductor chips.

6. The semiconductor package according to claim 1, wherein the interconnection structure comprises a first bonding layer having a plurality of first bonding pads, and the semiconductor chips comprises a second bonding layer having a plurality of second bonding pads, wherein the semiconductor chips are bonded to the interconnection structure by joining the plurality of first bonding pads to the plurality of second bonding pads.

7. The semiconductor package according to claim 6, wherein a portion of the plurality of first bonding pads are dummy pads that are electrically isolated from the semiconductor chips.

8. A semiconductor package, comprising:
a first package, wherein the first package comprises:
a porous substrate having a first surface and a second surface opposite to the first surface, wherein an amount of air voids located at the first surface is greater than an amount of air voids located at the second surface;
a plurality of semiconductor chips located on the porous substrate;
an interconnection structure electrically connected to the plurality of semiconductor chips; and
a plurality of conductive bumps electrically connected to the interconnection structure;
a circuit substrate, wherein the first package is bonded to circuit substrate so that the plurality of conductive bumps is joined with contact pads of the circuit substrate.

9. The semiconductor package according to claim 8, wherein the second surface of the porous substrate is free of the air voids.

10. The semiconductor package according to claim 8, wherein the second surface of the porous substrate include voids that are filled by a coating material, and the coating material includes flowable oxide materials or spin-on-glass (SOG) materials.

11. The semiconductor package according to claim 10, wherein a top surface of the coating material is aligned with the second surface of the porous substrate.

12. The semiconductor package according to claim 8, wherein the first package further comprises a first bonding film located on the porous substrate, and a second bonding film located in between the plurality of semiconductor chips and the first bonding film.

13. The semiconductor package according to claim 8, further comprising an underfill structure located on the circuit substrate and surrounding the plurality of conductive bumps of the first package.

14. The semiconductor package according to claim 8, wherein the first package further comprises a gap fill layer surrounding the plurality of semiconductor chips, and sidewalls of the gap fill layer are aligned with sidewalls of the porous substrate, and aligned with sidewalls of the interconnection structure.

15. A method of fabricating a semiconductor package comprising:
providing a substrate having a first surface and a second surface opposite to the first surface, wherein pores are located on the first surface and on the second surface of the substrate;
forming a coating material that entirely fills up the pores exposed on the second surface of the substrate;
forming a first bonding film on the substrate, wherein the first bonding film is contacting the coating material and the second surface of the substrate;
bonding semiconductor chips and an interconnection structure on the first bonding film, wherein the semiconductor chips are located on the first bonding film, and the interconnection structure is electrically connected to the semiconductor chips; and
forming a plurality of conductive bumps disposed on and electrically connected to the interconnection structure.

16. The method according to claim 15, wherein forming the coating material comprises performing a flowable oxide spin coating process to form flowable oxide materials in the pores exposed on the second surface of the substrate, and the flowable oxide spin coating process is performed under an ozone (O₃) atmosphere, and cured at a temperature of 150° C. to 800° C. with a curing time of 0.5 to 4 hours.

17. The method according to claim 15, wherein forming the coating material comprises performing a spin-on-glass (SOG) spin coating process to form SOG materials in the pores exposed on the second surface of the substrate, and the SOG spin coating process is performed under a nitrogen gas (N₂) atmosphere, and cured at a temperature of 150° C. to 300° C. with a curing time of 0.5 to 4 hours.

18. The method according to claim 15, wherein after forming the coating material, a polishing process is performed to remove portions of the coating material so that a top surface of the coating material is aligned with the second surface of the substrate.

19. The method according to claim 15, wherein the semiconductor chips and the interconnection structure are formed on a first carrier, and the semiconductor chips and the interconnection structure are bonded on the first bonding film by forming a second bonding film on the semiconductor chips and physically attaching the second bonding film to the first bonding film.

20. The method according to claim 19, wherein after attaching the second bonding film to the first bonding film, the first carrier is removed to reveal a surface of the interconnection structure, and the plurality of conductive bumps is formed on the surface of the interconnection structure.
